(19) United States
(12) Patent Application Publication
(10) Pub. No.: US 2007/0015357 A1
(43) Pub. Date: Jan. 18, 2007

(54) Process of adhesive bonding with patternable polymers for producing microstructure devices on a wafer assembly

(75) Inventors: Paul R. Ashley, Toney, AL (US); Mark G. Temmen, Toney, AL (US); Gerald Tuck, Madison, AL (US)

Correspondence Address: Jack Kenneth Greer, Jr.;U.S. Army Aviation and Missile Command, Legal Office, Bldg. 5300, 4th Floor, AMSAM-L-G-I, Huntsville, AL, 35898-5000, US

(73) Assignee: Government of the USA, as represented by Secretary of U.S. Army

(21) Appl. No.: 11/183,217

(22) Filed: Jul. 15, 2005

(51) Int. Cl. H01L 21/44

(52) U.S. Cl. 438/654

(57) ABSTRACT

A process for adhesive bonding of polymer layers between silicon substrates is disclosed for forming three-dimensional micro-structures on a silicon wafer. A base substrate such as a silicon wafer is provided and a coating step places at least one polymer thereon. At least one pattern is created in the polymer to form a plurality of channels and gaps in the polymer layer prior to precuring and curing. A second substrate is aligned adjacent to the base substrate and having the patterned polymer therebetween. The substrates and patterned polymer are cured under a vacuum and at selected temperatures to induce compression of the polymer between the substrates while retaining voids, channels and gaps in the polymer layer. Cooling forms layered polymer layers having voids, channels and gaps therein, forming three-dimensional micro-structures actuated by one or more optical, mechanical and fluidic forces to accomplish complex functions by the micro-structures.

### CROSS-REFERENCE TO RELATED APPLICATIONS

Not Applicable.

### STATEMENT REGARDING FEDERALLY SPONSORED RESEARCH OR DEVELOPMENT

The invention described herein may be manufactured, used and licensed by or for the Government for governmental purposes without the payment to the inventors of any royalties thereon.

### BACKGROUND OF THE INVENTION

1. Field of the Invention

The present invention relates to an adhesive process for producing three-dimensional microstructures on a silicon wafer surface. More specifically, the present invention relates to adhesive bonding of patterned polymer material at low temperatures on a silicon wafer surface and producing microstructures thereon.

2. Description of the Related Art

Numerous bonding techniques for production of polymer based wafers have been developed, including fusion bonding, anodic bonding, low-temperature glass bonding, eutectic alloy bonding and adhesive bonding. A relatively new method for wafer bonding includes use of polymers as an intermediate bonding material. The advantages of bonding with polymers include bonding on target wafer surfaces at relatively low temperatures compatible with production of CMOS circuits, and joining of various and different wafer substrates to form micro-devices between wafer surfaces. The disadvantages of recent methods of bonding with polymers include: (a) bonding with polymers as an intermediated material generally does not provide a hermetic seal; (b) limitations on temperature stability for polymers above about 500° C., such as fusion bonding at elevated temperatures of approximately 1100° C.; and (c) limitations on long-term stability for polymers bonded at elevated temperatures. A low temperature bonding process would provide long-term stability for the bonded polymers and the target wafer surfaces combined to form silicon-on-insulator (SOI) wafers, microfluidic devices having hybrid integration of CMOS and type III/V and II/VI compounds, fabrication of three dimensional micro-electromechanical systems (MEMS) and micro-optoelectromechanical systems (MOEMS).

Details relating to integrated circuits containing electrical and optical signals which are produced on multi-layer, multi-chip assemblies of MEMS and MOEMS are discussed in U.S. Pat. No. 5,761,350, issued to S. Koh. A method is disclosed for providing integration of electronic processing units for computer systems and communication networks, and for an apparatus including an optoelectronic multi-chip module assembly composed of double-sided polished silicon wafers having one side with at least one integrated optical waveguide fabricated thereon, and a second side having at least one integrated electrically conductive pathway fabricated thereon. The apparatus disclosed by Koh forms optoelectronic multichip modules (OE-MCMs) bonded together by techniques such as gold eutectic bonding or PRYEX® glass bonding, and further disclosed MEMS interconnections to provide integration of high speed electronic processing units and high bandwidth photonic interconnection networks. The materials utilized for fabrication on the silicon substrate wafers includes a polymer material such as a polyimide material. The method and apparatus of Koh does not provide low-temperature adhesive bonding of polymer materials on wafers to form micro-structures disposed on substrate materials such as PYREX®, alumina, or semiconductor materials such as type III/V and II/VI compounds.

U.S. Pat. No. 6,159,824, issued to F. Henley et al., discloses silicon-on-silicon (SOS) wafer bonding process using a thin film blister-separation method. The process for fabricating SOS wafers includes implanting hydrogen or helium ions through a thin surface film of silicon on a target silicon donor wafer, and bonding at a temperature of about 500° C., with resulting heating the wafer to induce microbubbles underneath the outer surface but without surface cracking in the microbubble region, and permanently bonding the thin film of silicon and the target silicon donor wafer by a high-temperature annealing process. The process of Henley et al., does not teach the use of alternative low-temperature adhesive bonding at temperatures of between about 250° C. to about 400° C., with polymer materials providing wafer to wafer distances of limited wafer separations allowing only bonding onto substrate materials such as PYREX®, alumina, or semiconductor materials such as type III/V and II/VI compounds, as provided in the present invention.

Accordingly, there is a need for a polymer wafer bonding process which allows relatively low temperature bonding with adhesives and polymers in order to produce multi-layer MEMS devices fabricated to include complex functionality as micro-structures having actuator movements to perform switching actions. An additional need is for a polymer wafer bonding process which allows relatively low temperature bonding between polymers and wafer surfaces to produce three-dimensional microstructures having patterned substrates thereon which function as micro-switches and micro-actuators.

### BRIEF SUMMARY OF THE INVENTION

The present invention provides a process of adhesive bonding of polymer layers between substrates, with adhesive bonding and patterning of the polymer layers forming a plurality of three-dimensional micro-structures on at least one silicon wafer surface. The process of adhesive bonding produces functional micro-mechanical structures, micro-fluidic devices and micro-electrical switches disposed on or between wafer surfaces. The process includes providing a base substrate disposed on a selected surface of a silicon wafer, with at least one polymer being coated on the base substrate. During the step of coating, the at least one polymer is bonded in a layer having a selected depth and width. A step of patterning creates a pattern in the polymer layer, with the pattern including voids forming a configuration having a three-dimensional micro-structure in the polymer layer. One or more steps of precuring provide for release of volatile byproducts from one or more layers of patterned polymers. A step of curing provides for the patterned polymer bonding in selected areas to the base substrate. A step of aligning is accomplished in the presence of a vacuum and includes a second substrate surface being aligned adjacent to the base substrate and having the patterned polymer interdisposed between. The base substrate, second substrate and polymer layer is cured in the presence of the vacuum and at a selected temperature resulting in inducing the base and second substrates to compress together thereby spreading the polymer between base and second substrates while retaining patterns and voids in the polymer layer. Cooling provides formation of a solidified polymer layer having a selected depth, a selected width, and having interdispersed voids and arcuate polymer surfaces between the base and second substrates separated a selected width apart by the solidified polymer layer. The method of bonding provides silicon wafer surfaces having at least one solidified polymer layer in which a plurality of arcuate flexible surfaces and intermittent spaced voids are formed into three-dimensional micro-structures which are readily actuatable by one or more optical, mechanical and fluidic forces for accomplishment of complex functions by the micro-structures when actuated by externally provided optical, mechanical and/or fluidic forces.

### BRIEF DESCRIPTION OF THE DRAWINGS

The present invention is illustrated in the drawings in which like element numbers represent like parts in each figure, including:

FIG. 1 is a side view of steps producing micro-structures composed of polymers coated and patterned on a wafer substrate in selected configurations;

FIG. 2 is a side view of a wafer substrate after numerous steps of the subject process, illustrating a patterned polymer coating disposed between wafer substrates;

FIG. 3 is a side view of one embodiment having a micro-structure assembly on a wafer substrate formed by the subject process;

FIG. 4 is a side view of an embodiment having a multi-layer assembly on a wafer substrate formed by the subject process;

FIG. 5 is a side view of an embodiment having a multi-layer assembly and micro-mechanical assemblies formed by the subject process on wafer substrates;

FIG. 6 is a side view of an embodiment having micro-mechanical assemblies aligned with micro-channels formed by the subject process on wafer substrates; and

FIG. 7 is a side view of an embodiment having multiple polymers bonded in multiple layers between wafer substrates.

### DETAILED DESCRIPTION OF THE INVENTION

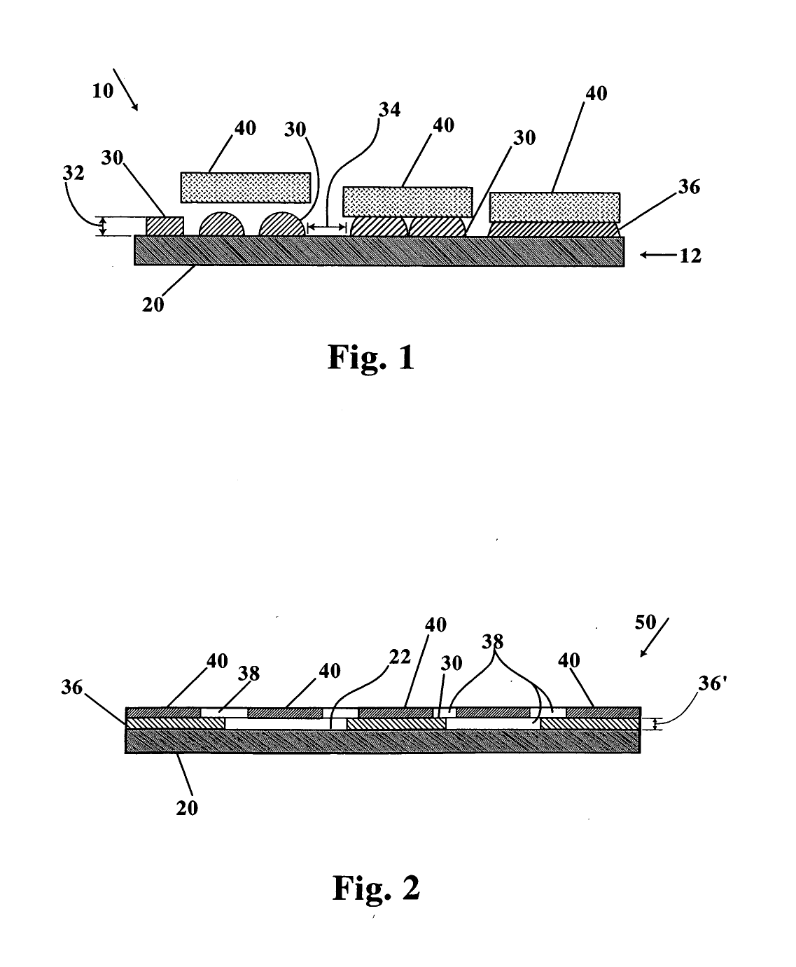

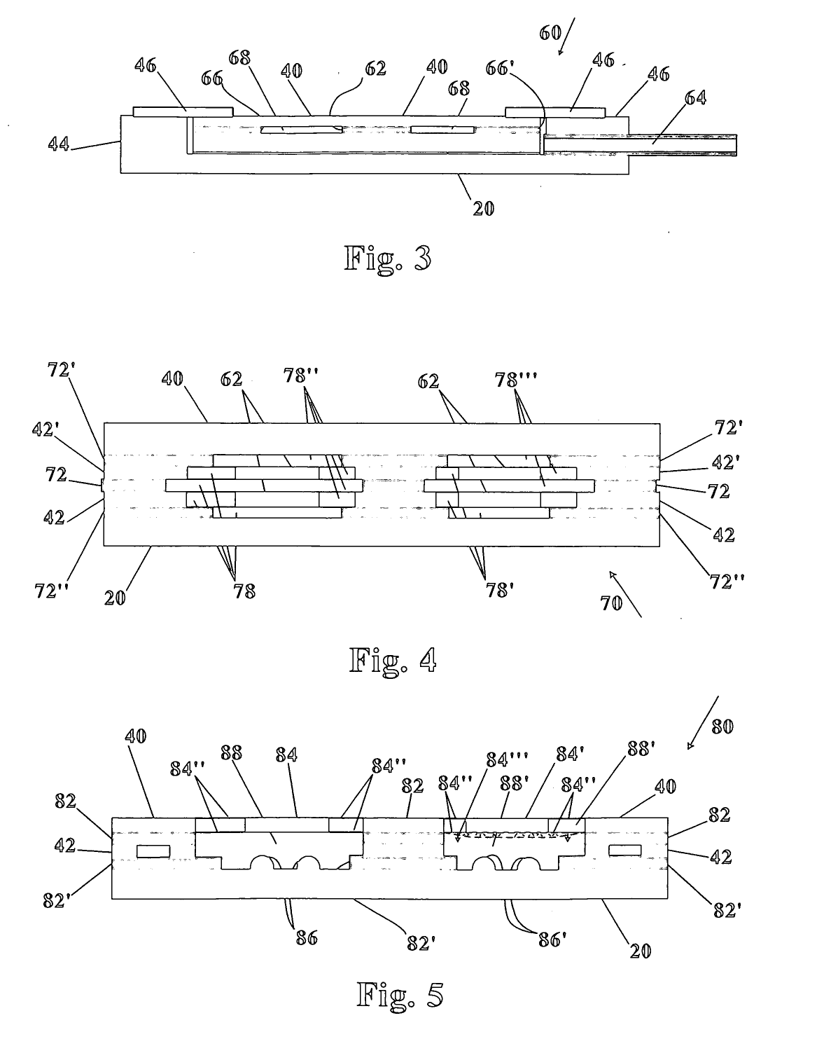

Referring now to FIGS. 1-7, a process for producing three-dimensional micro-structures in or on a silicon wafer 12 as illustrated at 10 in FIG. 1. The process includes a method of bonding a polymer material 30 and a plurality of wafer surfaces 20, 40 forming three-dimensional micro-structures 60, 70, 80, 90 (see FIGS. 3-6) between at least two wafer surfaces 20, 40 which are bonded together a selected distance apart 36. Upon curing, the polymer materials 30 are formed into micro-mechanical structures 62, 84, 84′ capable of performing repetitive movements and operations when manipulated by external generated electrical, mechanical and/or fluidic forces.

A base substrate 20 is provided such as a silicon wafer which includes compositions such as a SOS wafer or a SOI wafer. The base substrate 20 provides a base on which at least one polymer coating is applied in selected configurations (see FIGS. 1-7). The base substrate 20 is composed of material compatible with the process of coating polymers thereon, including materials such as silicon, silicon carbide, silicon dioxide, silicon nitride, and sapphire. Combinations of the above materials and additional materials are also utilizable such as metals including Kovar® compounds, gold, aluminum, chromium and titanium and other metals known to those skilled in the art relating to constructing micro-structures on one or more wafer surfaces 20, 40. The materials utilized to generate the base substrate 20 are preferably disposed on a wafer receiving surface 22 in layers applied by techniques such as photolithography, vacuum depositions, or dry or wet etching techniques. After deposition of polymer material 30 on the wafer receiving surface 22, the polymer material 30 is patterned and bonded on the receiving surface 22 to form one or a plurality of three-dimensional micro-structures without an immediate need for additional coating steps and bonding steps other than curing the base substrate wafer surface 20 and the at least one polymer material 30 bonded thereon.

The polymer coating 30 includes adhesive properties which allow bonding to the base substrate surfaces 20 of the polymer coating 30 after the step of patterning. A conditioning of the polymer coating 30 on the base substrate 20 is induced during a step of precuring in order to release volatile byproducts from the polymer coating. Precuring progresses at relatively low temperatures in a range of between about 250° C. to about 350° C. (see FIGS. 1 and 2). The relatively low temperature range for precuring and bonding of the polymer coating 30 to the substrate surfaces 20 is significantly lower than the generally utilized temperature for fusion bonding (approximately 1100° C.). One preferred range for the precuring step is between about 270° C. and about 350° C. One polymer found to be well suited for use in the process of the subject invention is DuPont 2700 series photosensitive polyimide. Other polymer materials which are utilizable for adhesive bonding include polyimides, epoxies, thermoplastic adhesives, and photoresisting adhesives. Selection of the polymer materials utilized in the step of coating is related to the number of layers applied for one or more types of coatings, whether areas of the polymer are required to be optically transparent, and/or whether channels and vent holes are required in the polymer to provide micro-fluidic channels.

The step of patterning the polymer coating on the base substrate is accomplished to create a selected configuration for the polymer coating having a plurality of channels and gaps in the polymer coating depending on the type of micro-machine device which is intended to be created within the polymer coating. The steps of coating and patterning provide a patterned polymer coating 30 having a selected configuration in which at least one layer of coating 30 has a pre-heated depth 32 of between about 1.5 microns to about 40 microns on the base substrate 20 (see FIG. 1). The patterned polymer coating 30 includes spaced apart gaps implemented by conventional photolithographic techniques, or dry or wet etching techniques. Various thicknesses of polymer coating 30 may be accumulated by repetitive polymer coating steps across a width 34 and length of base substrate 20 (see FIGS. 4-7).

The patterned polymer coating 30 is heated on the base substrate 20 during the precuring step which allows release of volatile and reaction products, along with shaping of a patterned polymer layer 32 in a selected width 34 having a plurality of void spaces and gaps 38 therein (see FIG. 2). The void spaces and gaps 38 created by the steps of patterning and precuring provides vent channels to allow gasses such as chemical reaction products of imidization to be vented during precuring of the polymer coating, thereby providing strong void-free bonds between the bonded polymers across the width and length of the base substrate 20. If vent channels are not provided during curing of the polymer(s), chemical reaction product gasses may be retained within each bonding layer during curing and cooling, thereby causing unwanted void spaces which reduce adhesion in bonding layers and reduce long-term stability of bonding to the base substrate 20.

Upon completion of the patterning and precuring steps for the patterned polymer layer 32 disposed on the base substrate 20, a second substrate 40 is aligned adjacent with the base substrate 20 in order to bound the patterned polymer width 34 between the substrate layers 20, 40, thereby forming a silicon wafer 12 having a unique layered composition. The silicon wafer 12 having the patterned polymer layer 32 interdisposed between substrates 20, 40 is cured under a vacuum at selected temperatures of between about 250° C. and about 400° C. The step of curing can include placing one or more patterned polymer layers 62 positioned between substrates 20, 40 in a vacuum bake apparatus 44 having sufficient silicon, rubber or similar gasket materials 46 to enclose a layered assembly 60. A vacuum is maintained within the polymer layer 62 by at least one tubule 64 being positioned proximal of the polymer layer 62 (see FIG. 3), for removal of imidization gasses during curing. Curing under a vacuum induces substrates 20, 40 to become bonded to opposed surfaces of a compressed polymer layer 66 which is spread laterally while retaining void spaces and gaps 68 therein, forming a compressed polymer depth 36′ or 66′. One skilled in the art will recognize that multiple precuring steps can be interdisposed between steps of coating, patterning, and aligning of substrates 20, 40.

The step of curing is followed by a step of cooling of the substrates and the compressed polymer coating 36 to provide a selected depth 36′ of between about 1.0 microns and about 30 microns for a depth of separation between the polymer bonded surfaces of the substrates 20, 40. The depth of separation provided by the solidified polymer layer 36 and the interdisposed voids and gaps 38, allows for large actuator movements of levers formed by arcuate surfaces crafted by the process to form a bonded assembly 50 within a silicon wafer (see FIG. 2). The process for producing three-dimensional micro-structures can include bonding together of numerous bonded assemblies 50, to form multi-layered assemblies 60, 70 (see FIGS. 3 and 4). A three-dimensional micro-structure 60 can be produced as illustrated in FIG. 3, including spaced openings and gaps 68 within a polymer 62 interdisposed between outer substrate layers 20, 40, which are bonded to the polymer layer 66 during the steps of curing and cooling of the process of the subject invention.

An additional embodiment of the process for producing three-dimensional micro-structures on silicon wafers includes repetitive steps of coating a plurality of layers of polymers 72, 82, 92, 112 on at least one substrate such as a wafer. Each repetitive step of coating is followed by steps of patterning and precuring each layer of polymer in order to shape the polymer and to release volatile byproducts from each polymer layer. Additional steps of aligning and bonding second and third substrates can be incorporated in the process, with intermediate steps of precuring and curing, in order to form any one of a plurality of three-dimensional micro-structures 70, 80, 90 and 100 (see FIGS. 4-7) interdisposed between outer layers of substrates 20, 40, and any intermediary layers of substrate 42, 42′. The multiple polymer layers disposed between substrate layers form a silicon wafer produced by the process of the subject invention and provides MEMS devices having three-dimensional micro-structures having sufficient depths of separation, and associated gaps and channels therein, to allow actuatable movements for levers and associated arcuate surfaces of respective micro-structures 70, 80, 90 and 100 to be readily manipulated over actuator distances of about 1.0 microns to about 30 microns by externally generated optical, electrical, mechanical and/or fluidic forces.

As illustrated in FIG. 4, a multi-layered assembly is built by stacking with a like-configured silicon wafer having the three-dimensional micro-structure 60 thereon, to provide a multi-layered assembly 70. Additional steps of polymer coating are utilized to seal and bond one or more polymer materials 72, 72′, 72″ in successive polymer layers having intermediary substrate layers 42, 42′ to form a multi-layered assembly 70 having a plurality of stacked and aligned channels 78, 78′, 78″, 78″′ (see FIG. 4). Each step of coating of one or more types of polymer materials is followed by sequential steps of patterning each successive layer of polymer material before steps of aligning the intermediary substrate layers 42, 42′, and the steps of curing and cooling are applied to produce the multi-layered assembly 70. Each patterning step provides a plurality of channels and gaps in each respective polymer layer 72, 72, 72′, 72″, with successive channels and gaps being aligned, or not aligned with adjacent polymer layers, depending on the design parameters and the selected configuration intended for the three-dimensional micro-structure built within the outer base substrate 20 and the outer second substrate 40.

As illustrated in FIG. 5, a multi-level assembly 80 is a product of the process of the subject invention. The multi-level assembly 80 is configured to include at least two stacked, like-configured silicon wafers having multiple layers of polymer coating 82, 82′ bonded between one or more outer substrates 20, 40, and intermediary substrates 42, 42′ stacked between polymer layers in which interior gaps and channels 88, 88′ have been patterned therein (see FIG. 5). During the steps of coating and patterning of each layer of polymer 82, 82′, one or more micro-lever assemblies 84, 84′ are created having arcuate supporting ends 84″ which are composed of a flexible thickness of silicon, silicon nitride, polymer material, or similar materials, extending from a mid-portion thickness of polymer material connected between the supporting ends 84″. Each micro-lever assembly 84, 84′ is reciprocatingly moved 84″′ into each respective interior gap and channel 88, 88′ by one or more externally provided electrical, mechanical and/or fluidic forces. Also, during the steps of coating and patterning of each layer of polymer 82, 82′, one or more detent or standoff structures 86, 86′ are disposed within each respective gap and channel 88, 88′, such that each standoff structure 86, 86′ is composed of a raised polymer material or a raised electrical conducting material. When electrical, mechanical and/or fluidic forces activate and reciprocatingly move 84″′ each micro-lever assembly 84, 84′, the lever portion is contacted against respective standoff structures 86, 86′, thereby providing a limit to movement and limiting contact with wafer substrate surface 20, and further providing a plurality of electrical contacts with standoff structures 86, 86′ with resulting creation of micro-switches which are electromechanical in function.

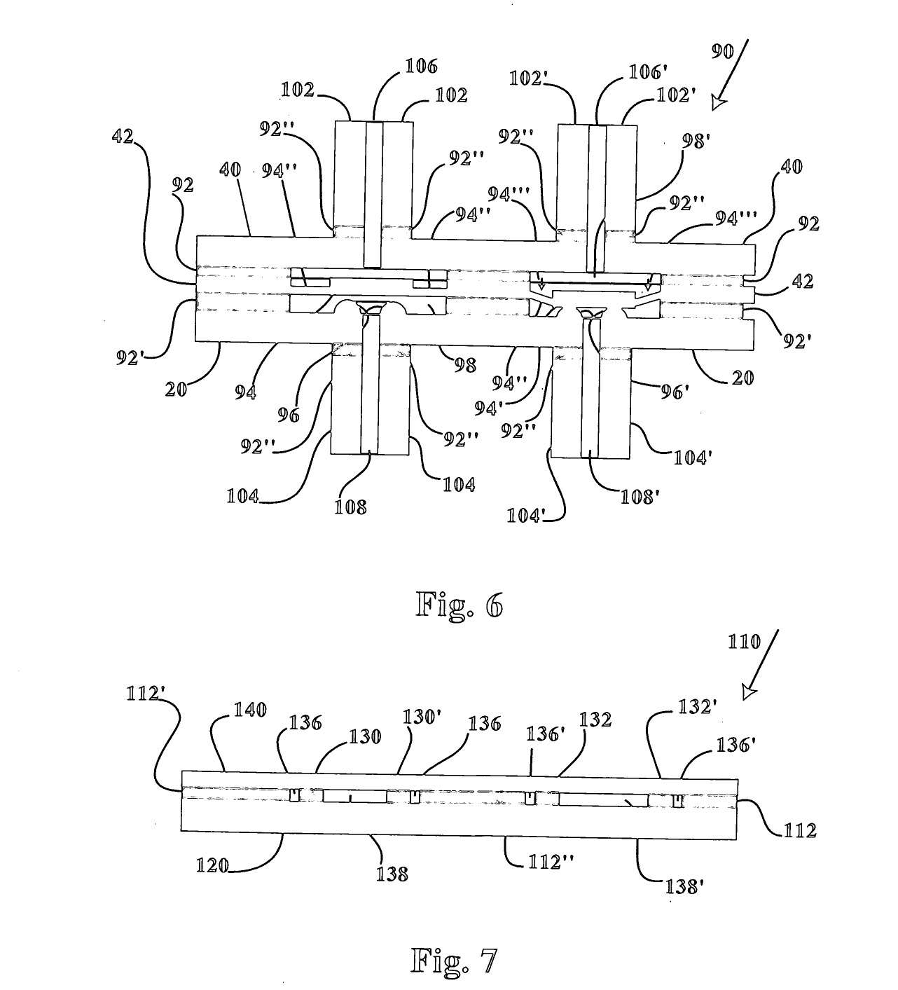

Illustrated in FIG. 6 is a micro-assembly 90 product of the process of the subject invention which includes components configured as illustrated in FIG. 5, and incorporating additional hollow wafer structures 102, 104 forming fluid or gas inlet channels 106, 106′ which direct fluids and/or gases toward one or more micro-valve assemblies 94, 94′ positioned within interior voids 98, 98′ for control of fluid flow through exit channels 108, 108′. The micro-assembly 90 includes at least two stacked, like-configured silicon wafers having multiple layers of polymer coating 92, 92′ bonded between outer substrates 20, 40, and having intermediary substrates 42, 42′ stacked between the polymer layers in which interior voids 98, 98′ have been constructed (see FIG. 6). During the steps of coating and patterning of each layer of polymer 92, 92′, one or more micro-valve lever assemblies 94, 94′ are created having arcuate attaching ends 94″ which are bendable and composed of a silicon, silicon nitride, flexible polymer material, or similar material, extending from a mid-portion polymer material forming the lever assembly 94, 94′ connected between attaching ends 94″. Each micro-valve assembly 94, 94′ is reciprocatingly moved 94″′ in each respective interior voids 98, 98′ to occlude flow, or to allow fluidic or gas flow in channels 106, 106′. Also during the steps of coating and patterning of each layer of polymer 92, 92′, one or more valve detent structures 96, 96′ are disposed within each respective voids 98, 98′, such that each valve detent structure 96, 96′ is composed of a raised polymer material, or a raised electrical conducting material if electrical contacts are desired. Flow of fluid or gas through inlet channels 106, 106′ can activate each micro-valve assembly 94, 94′ leading to the valve/lever portion contacting against respective valve detent structures 96, 96′ to close the valve opening. The fluids or gasses are channeled to impact against the micro-valves 94, 94′ (if closed), and flow around the micro-valves 94, 94′ (if opened), by having one or more channels 102, 102′, 104, 104′ bonded with polymers to the micro-assembly 90, to form fluid or gas flow inlet channels 106, 106′ and exit channels 108, 108′ in fluid communication with interior voids 98, 98′ within the polymer layers 92, 92′. The channels 102, 102′, 104, 104′ are formed with substrate layers and polymers 92″, 92″′ utilizing additional process steps of forming and bonding the channel structures 102, 102′, 104, 104′ in abutting or perpendicular configurations (see FIG. 6) in relation to the outer substrates 20, 40 through which an adequate number of fluid or gas flow openings are provided during repetitive steps of coating and patterning polymers on the outer substrates (see FIGS. 1-3).

As illustrated in FIG. 7, a multi-layered micro-assembly 110 is a product of the process of the subject invention and includes a variety of polymers utilized for bonding and spacing apart substrates 120, 140 during steps of heating, aligning and curing as illustrated in FIGS. 1-3). Polymers for base layers 112, 112′, 112″ which are compatible with the process of the subject invention include DuPont 2700 series photosensitive polyimide which soften and reflow at precuring and curing temperatures in the range of about 250° C. and about 400° C. Additional polymers 130 compatible with the process include DuPont 2545 polyimide which does not reflow after the curing step and does not typically adhere on contact with other substrates 120, 140 during curing. The additional polymers 130 are utilized during repetitive steps of coating and patterning to produce spacers 130, 130′, 132, 132′ which separate void spaces 136, 136′, and gaps 138, 138′ between substrates and between the polymer base layers 112, 112′, 112″. Other polymer materials which are utilizable in the process of the subject invention include polyimides, epoxies, thermoplastic adhesives, and photoresisting adhesives. Selection of the polymer materials is related to the number of layers and void spaces required for the three-dimensional micro-structures being built on wafers, and whether the polymer layers must be optically transparent, and/or mechanically stiff or flexible.

Numerous alternative bonding techniques are utilizable for production of polymer based wafers have been developed, including fusion bonding, anodic bonding, low-temperature glass bonding, eutectic alloy bonding and adhesive bonding. During utilization of adhesive bonding, a polymer is used as an intermediate bonding material. Typical polymers utilized in adhesive bonding include polyimides, epoxies, thermoplastic adhesives, and photoresisting adhesives. The advantages of adhesive bonding with polymers include: (a) bonding at relatively low temperatures is possible in a range of between about 100° C. to about 300° C., depending on the adhesive material, thereby bonding is compatible with production of CMOS circuits; (b) joining of various wafer substrates is possible; (c) toleration of particles and/or structures on the substrate surface is possible during bonding when the dimensions are not greater than the adhesive thickness; (d) achieving high bonding strengths; (e) providing low processing costs; and (f) providing compatibility of numerous adhesive materials with standard clean room processing of wafers. A partial sampling of applications for low temperature adhesive bonding includes producing silicon-on-insulator (SOI) wafers, microfluidic devices, hybrid integration of CMOS and type III/V and II/VI compounds, and fabrication of 3D micro-electromechanical systems (MEMS) and micro-optoelectromechanical systems (MOEMS).

The disadvantages of prior methods of adhesive bonding with polymers include: (a) bonding with polymers as an intermediated material generally does not provide a hermetic seal; (b) limitations on temperature stability for some polymers at temperatures less than about 400° C.; and (c) limitations on long-term stability for some polymers. Each of the above stated disadvantages of prior methods of adhesive bonding are addressed and corrected by the process of the current invention.

While numerous embodiments and methods of use for this invention are illustrated and disclosed herein, it will be recognized that various modifications and embodiments of the invention may be employed without departing from the spirit and scope of the invention as set forth in the appended claims. Further, the disclosed invention is intended to cover all modifications and alternate methods falling within the spirit and scope of the invention as set forth in the appended claims.

What is claimed is:

1. A method of bonding a plurality of layers forming three-dimensional micro-structures on a silicon wafer surface, comprising the steps of:
(a) providing a base substrate disposed on a selected surface of a silicon wafer;
(b) coating a polymer on said base substrate at a selected depth and width;
(c) patterning said polymer on said base substrate in a selected configuration having a plurality of channels and gaps in said polymer;
(d) precuring said patterned polymer on said base substrate, said step of precuring providing for release of volatile byproducts from said patterned polymer; and
(e) curing said base substrate under a vacuum at a selected temperature whereby said step of curing induces said patterned polymer to be compressed and bonded in a bonded polymer layer along said selected areas of said base substrate;
whereby said bonded polymer layer having said plurality of arcuate surfaces and intermittent spaced gaps forming three-dimensional micro-structures which are actuatable by one or more optical, mechanical and fluidic forces.

2. The method of claim 1, further comprising:
(i) repeating said step of coating with a second polymer disposed in a second layer on said patterned polymer;
(ii) repeating said step of patterning with said second polymer to form additional channels and gaps in said second polymer; and
(iii) aligning a second substrate adjacent to said base substrate with said patterned polymer and said second polymer interdisposed between said base and second substrates, said aligning step proceeding prior to said step of curing;
(iv) bonding by heating said patterned polymer and said second polymer with resulting bonding of said polymers between said base and second substrates; and
(v) cooling said base and second substrates and polymer layers, with formation of stratified and patterned polymer layers having respective selected depths and selected widths in which a plurality of arcuate surfaces are interdisposed with intermittent spaced gaps formed between base and second substrates.

3. The method of claim 2 wherein the step of bonding further including compressing said polymer patterned on said base substrate to a selected separation between said base substrate and said second substrate, said step of compressing retaining said plurality of channels and gaps in said polymer thereby providing spacing within said polymer layer for actuation of said at least one three-dimensional micro-structure by one or more optical, mechanical and fluidic forces.

4. The method of claim 2 wherein the step of curing further including said polymer layer having said selected depth of between about 1.0 microns to about 30 microns separation between said base substrate and said second substrate.

5. The method of claim 1 wherein the step of coating includes utilizing a photosensitive polyimide polymer, the step of coating further including repeating said step of coating with a plurality of layers of said photosensitive polyimide polymer on said base substrate and patterning each of said plurality of layers of said photosensitive polymer thereby forming a plurality of channels and gaps in each layer.

6. The method of claim 2 wherein the steps of curing and bonding includes heating said patterned polymers and each substrate utilizing selected temperatures of between about 250° C. and about 400° C.

7. The method of claim 2 wherein the step of precuring includes heating said patterned polymers and said substrates utilizing selected temperatures of between about 250° C. and about 350° C.

8. A process for producing three-dimensional micro-structures on silicon wafer surfaces, comprising the steps of:
(a) providing a base substrate disposed on a selected surface of a silicon wafer;
(b) coating a base polymer on said base substrate at a selected depth and width;
(c) patterning said base polymer to form a first polymer layer having a plurality of channels and gaps therein;
(d) applying an additional polymer in selected areas on said patterned base polymer;
(e) patterning said additional polymer to form a second polymer layer having a depth in which a plurality of channels and gaps are disposed adjacent said patterned base polymer;
(f) precuring said patterned base and additional polymers, said step of precuring providing for release of volatile byproducts from said patterned polymers;
(g) curing said patterned polymers under a vacuum at a selected temperature, said step of curing induces bonding of said patterned base polymer and patterned additional polymer and further induces compressing of said polymers along selected areas of said base substrate, said step of curing provides fixation of respective channels and gaps thereby forming a plurality of arcuate surfaces interdisposed with said channels and gaps within respective base polymer and additional polymer layers;
(h) aligning a second substrate adjacent to said base substrate and having said patterned base and additional polymer layers interdisposed between, said aligning step being accomplished in the presence of said vacuum;
(i) heating said base polymer and additional polymer layers and said base and second substrates in the presence of said vacuum at a selected temperature whereby said step of curing induces each of said polymer layers to be compressed and spread laterally between respective base and second substrate with retention of said plurality of channels and gaps in respective polymer layers; and
(j) cooling said base and additional polymer layers and said base and second substrates with formation of solidified polymer layers having a selected depth separation between said base and second substrates;
whereby said solidified base and additional polymer layers having said plurality of channels and gaps form a plurality of three-dimensional micro-structures having said plurality of arcuate surfaces which are readily actuatable within said selected depth separation by one or more optical, mechanical and fluidic forces.

9. The process of claim 8 wherein the step of patterning further including aligning said plurality of channels and gaps in each polymer layer to provide a plurality of spaced apart void spaces between said base substrate and said second substrate, whereby said plurality of void spaces retain alignment during said step of curing thereby providing sufficient void spacing within said polymer layers for movement of said plurality of arcuate surfaces of said three-dimensional micro-structures by one or more optical, mechanical and fluidic forces.

10. The process of claim 9 wherein the step of curing further including said polymer layers having said selected depth separation of between about 1.0 microns to about 30 microns separation between said base substrate and said second substrate.

11. The process of claim 10 wherein the steps of coating and applying said additional polymer include providing at least one photosensitive polyimide which is readily patterned to form said aligned channels and gaps within each respective polymer layer.

12. The process of claim 11 wherein the steps of curing and heating includes said patterned polymers and substrates being heated to selected temperatures of between about 300° C. and about 400° C.

13. The process of claim 9 wherein the step of precuring includes heating said patterned polymer, said base substrate and said second substrate utilizing selected temperatures of between about 250° C. and about 350° C.

14. The three-dimensional micro-structure produced by the process of claim 10 wherein the three-dimensional micro-structure includes a plurality of polymer layers having said aligned channels and gaps in which said plurality of arcuate surfaces are readily actuated within said selected depth separation by mechanical or fluidic forces.

15. The three-dimensional micro-structure produced by the process of claim 11 wherein the three-dimensional micro-structure includes said at least one photosensitive polyimide being patterned to form said plurality of arcuate surfaces readily actuated within said selected depth separation by an optical force.

16. A three-dimensional micro-structure on a silicon wafer, comprising:
a base substrate disposed on a selected surface of a silicon wafer;
a base polymer coated on said base substrate, said base polymer coating having a selected depth and width;
said base polymer being patterned and precured at a selected temperature to form a first patterned polymer layer having a plurality of channels and gaps therein;
an additional polymer applied on said patterned base polymer, said additional polymer being patterned to form an additional patterned polymer layer having channels and gaps therein and disposed adjacent of said plurality of channels and gaps in said first patterned polymer layer;
a second substrate aligned in adjacent orientation to said base substrate with said first patterned polymer layer and additional patterned polymer layer interdisposed between said substrates to form a selected depth separation; and
said first patterned polymer layer and additional patterned polymer layer are cured to said selected temperature in a vacuum resulting in bonding in respective layers interdisposed between said substrates, said first patterned polymer layer and additional patterned polymer layer having a plurality of arcuate surfaces interdisposed with said channels and gaps of respective patterned polymer layers;
whereby said first patterned polymer layer and additional patterned polymer layers having said plurality of channels and gaps therein provide three-dimensional micro-structures having said plurality of arcuate surfaces being actuatable within said selected depth separation by one or more optical, mechanical and fluidic forces.

17. The three-dimensional micro-structure of claim 16 wherein said selected depth separation includes separation of between about 1.0 microns to about 30 microns between said base substrate and said second substrate.

18. The three-dimensional micro-structure of claim 17 wherein said additional polymer includes at least one photosensitive polyimide which is patterned at said selected temperature and vacuum for formation of said channels and gaps having said plurality of arcuate surfaces within said selected depth separation, whereby said plurality of arcuate surfaces are actuatable by optical forces.

19. The three-dimensional micro-structure of claim 18 wherein said selected temperature includes temperatures of between about 250° C. and about 400° C.

20. The three-dimensional micro-structure of claim 19 wherein said plurality of channels and gaps are aligned to form a fluid channel through said micro-structure, and further including said plurality of arcuate surfaces being configured to include at least one movable valve or lever configuration disposed to reciprocate between an occluding position and a non-occluding position of at least one channel within said selected depth separation, whereby said at least one movable valve or lever is reciprocatingly actuated by one or more mechanical and fluidic forces.
